(19) United States
(12) Patent Application Publication
(10) Pub. No.: US 2021/0223314 A1
(43) Pub. Date: Jul. 22, 2021

(54) Vector Eyes

(71) Applicants: Richard C. Carmichael, San Jose, CA (US); David Reynolds, Gilford, NH (US)

(72) Inventors: Richard C. Carmichael, San Jose, CA (US); David Reynolds, Gilford, NH (US)

(21) Appl. No.: 16/744,921

(22) Filed: Jan. 16, 2020

(51) Int. Cl. G01R 31/3183; G01R 31/319; G01R 31/30; G11C 29/56

(52) U.S. Cl. CPC G01R 31/318307; G01R 31/31907; G01R 31/31908; G11C 29/56; G01R 31/31926; G01R 31/3004; G01R 31/318342

(57) ABSTRACT

Systems and methods are disclosed for testing a device under test (DUT) by receiving a test pattern for a functional test, wherein the test pattern includes a test vector, an expected test result, and an expected power consumption; instructing the test system to run a repetitive loop using a selected functional test as the stimulus; at selected steps in the functional test, measuring power consumption of the DUT; and validating the DUT based on validating the test vector and the power consumption with one or more expected test result patterns and expected power consumption patterns.

### BACKGROUND

The present invention relates to testing of electronic circuits.

In designing and producing integrated circuits (IC's), today's semiconductor manufacturers have very sophisticated tools to analyze their designs via computer simulations and analysis. These tools allow the engineers to present information to their design and see if it reacts in the way that is expected. And these tools have reached capabilities that without them, the chips that are in our cell phones for example, would be impossible to make work.

However, those simulations are not the actual IC operating. The analysis of the actual performance of the IC is left to the “Test Team”. This team, which typically includes design and test engineers, utilize today's automatic IC test systems to both stimulate the IC and measure its response.

However, the visibility into the functionality of the majority of circuits on an IC is limited. From the normal connections to the IC, test engineers can only directly stimulate and measure a small portion of the circuits. These circuits, known collectively as the input/output pins, give access to less than 5% of the total circuits on the IC and many times less than 1%.

Test structures such as JTAG are added to IC designs so the test teams can load information into the inter-circuits, test their functionality and then “shift” the data out for analysis. These JTAG circuits are used only for test and typically have nothing to do with the functionality of the IC. They are also limited in that the JTAG data shows the engineers information that changed many digital steps earlier. Very little information is provided about the dynamic operation of those circuits.

### SUMMARY

In one aspect, a technique is disclosed for analyzing the inter-workings of an integrated circuit by measuring the current being consumed by that integrated circuit at selected points in a functional test. The technique requires the proper algorithm, a computer system, measurement hardware and a graphical analysis tool to provide insight into the data accumulated and the functioning of the integrated circuit.

In another aspect, a method for testing an integrated circuit (IC) includes: instructing the test system to run a repetitive loop using a selected functional test as the stimulus; at selected steps in the functional test, measuring and recording one or more currents being consumed by the IC.

In another aspect, systems and methods are disclosed for testing a device under test (DUT) by receiving a test pattern for a functional test, wherein the test pattern includes a test vector, an expected test result, and an expected power consumption; instructing the test system to run a repetitive loop using a selected functional test as the stimulus; at selected steps in the functional test, measuring power consumption of the DUT; and validating the DUT based on validating the test vector and the power consumption with one or more expected test result patterns and expected power consumption patterns. For example, in implementations, the power may be consumed by one or more pins on the IC. The system tracks the current of multiple supplies, at various voltages, as part of the measurement.

Advantages of the system may include one or more of the following. The system gives professional integrated circuit designers and their teams an effective tool to look inside today's ultra-complex circuits—discovering and confirming what is really going on. The system's capability can have positive impact on yet another aspect of the semiconductor industry. There is often fear that during design and fabrication, unauthorized circuits could be added to the design that would give certain individuals ways to usurp any security precautions. Semiconductor designers and manufacturers can use the device profiles generated by the instant system to make sure that any unexpected operation of the chip indicative of unwanted circuitry or tampering attempt is detected and analyzed.

Other advantages of the present system may include one or more of the following. The system enhances test performance and decrease the test time and error ratio and cost of the products. In contrast to the “rack-n-stack” instruments available for the engineering bench or after thought add-ons to an existing test system, the blades are carefully architected to assure precise synchronization, short test times and production worthy stability. Rather than accept general-purpose solutions trying to solve a wide set of generic needs, Cobra blades focus on the key issues that minimize the real cost of each test challenge. This maximizes the utilization of the purchased capital, directly lowering the Cost Of Test for the user.

The system's centralized power distribution system assures that all instruments have the precise set of voltages and currents desired, in a low-noise environment. This arrangement provides a simplified power distribution to provide a more reliable ATE system by limiting the diversity of bulk power supplies to one voltage. The custom-tailored power requirements for now and the future based upon a single voltage reference provided to all major components of Automatic Test Equipment. Power distribution of a single voltage reference has been historically impractical to implement given the circuit demands of Automatic Test Equipment, but this is made possible using the centralized power distribution of the present system.

Another advantage of the system is offered through the “Central Reference Clock” subsystem. A stable, precision oscillator provides the “heartbeat” for test functions and is broadcasted to all instruments. This reference clock is physically connected at the center of the Cobra Motherboard—an origin point that facilitates a clock distribution that approaches “Zero Clock Skew”.

### BRIEF DESCRIPTION OF THE DRAWINGS

FIG. 1 shows an exemplary tester system.

FIGS. 2-4 show exemplary test diagrams.

FIG. 5A shows an exemplary tester system.

FIG. 5B shows an exemplary tester with a four-blade cut away.

FIG. 5C shows the tester of FIG. 1 with a control computer.

FIG. 5D shows an exemplary cross-sectional side view of the system.

FIG. 6A shows an exemplary PCIe cable interface.

FIG. 6B shows an exemplary arrangement for minimizing noise for multiple blade instruments.

### DETAILED DESCRIPTION

In the following description, details of various implementations are set forth to provide a more thorough explanation of embodiments of the present invention. However, it will be apparent to one skilled in the art that embodiments of the present invention may be practiced without these specific details. In other instances, well-known structures and devices are shown in block diagram form rather than in detail in order to avoid obscuring embodiments of the present invention. In addition, features of the different embodiments described hereinafter may be combined with each other, unless specifically noted otherwise.

One embodiment called VectorEyes expands the engineers' visibility into the operation of integrated circuits (ICs). VectorEyes does this by instructing the test system to run a repetitive loop using a selected functional test as the stimulus. Then, at selected steps in the functional test, measure and record the supply current being consumed by the IC. The power may be consumed by one or more pins on the IC. The system tracks the current of multiple supplies, at various voltages, as part of the measurement.

The term Vector, as used herein and commonly used in the IC test industry, refers to the pattern of 1's and 0's that are either being sent to the IC being tested (known as the DUT for device under test), or expected back from the DUT. Each vector represents one step in a functional test pattern. Production IC tests may contain one or more of these “vector patterns” with each pattern containing one or more vectors. Million step patterns are not uncommon. The pattern used herein includes over 600,000 vectors.

These vector patterns are developed during the design simulations and represent the engineering team's “best effort” at insuring proper IC performance. Best effort referring to the fact that exhaustive testing of today's IC's would take many millions of years to complete. Note that a circuit with only 55 transistors would take 1.13 years at 10 GHz to exhaustively test. Today's circuits have million and even billions of transistors.

The VectorEyes Process is detailed next. The software application and the test hardware allow the user to select any valid vector pattern as the digital stimulus for the test. The user can also select which of the IC's power supplies will be part of the test.

The user then directs the system which sections of the functional test pattern should be used for the measurement portion of the testing. This allows engineers to focus on certain areas of interest, without waiting for data from areas of the vector pattern of less concern.

The user can set:
which vector should start the functional test (normally 0, but not always)
which vector to start making current measurements
how many vector steps between measurement
which vector to stop the testing
the delay from stopping on a vector to making first measurement (10 us+)

As well, the software allows the user to select the number of current measurements to make at each vector being measured. While currents can be seen by a single measurement, fixturing noise makes interpretation of the data difficult, if not impossible. But, by utilizing the “Law of Large Numbers” first described by Italian mathematician Gerolamo Cardano (1501-1576), measurements that peer down through the noise to see the real information are possible with impressive resolution and stability.

By making hundreds or even thousands of measurements at each measurement point, any random noise is averaged away. And, for every doubling in the number of samples, the resolution of the test hardware is increase by 0.41% or doubled every factor of four. For example, making 1024 measurements allows a 16-bit measurement system to measure with 21 bit or 0.0000476% resolution, while decreasing the noise by a factor of 32.

There are two other considerations regarding the actual current measurement and both involve time. The test system utilized herein can stop the pattern at a measurement point and make a first measurement in under 50 uS with subsequent multi-sample measurements made every 37 uS. As well, the user can select additional delay times (microseconds to seconds) before starting the first measurement. Both the time to make a measurement and the optional delay can affect the results.

As the time from the last vector execution increases, observed waveforms can very dependent on the network associated with the power pin of the device under test and what circuits on the DUT are consuming power.

Test fixtures normally have lumped capacitance very near the actual device power pin to smooth out the power supply fluctuations caused during its normal operation. When the device is used in its eventual customer's product circuit, that circuit will also include similar lumped or “bypass” capacitance. Values of 0.1 ufd to 1.0 ufd are common. The effects of these bypass capacitors must be taken into consideration when interpreting the VectorEyes data.

The vector pattern is presented to the device under test in a repetitive loop in one of two sequences. The first type, dynamic, starts at the first vector and then executes vectors until the next measurement point. It makes a measurement and then returns to the first vector and re-executes the pattern up to the last measurement point plus the vector steps between measurements. It does this until it is at or beyond the stop vector.

The dynamic vector address sequence for a pattern starting at 0, for 8 vectors, stepping by two vectors would be: 0, 1, M, 0, 1, 2, 3, M, 0, 1, 2, 3, 4, 5, M, 0, 1, 2, 3, 4, 5, 6, 7, M (the M's indicate when the current measurement is made).

The static sequence is simpler. It starts at the first address and increments that address to the next measurement point. It continues this until it is at the stop address. The static address sequence for the same parameters above would be: 0, 1, M, 2, 3, M, 4, 5, M, 6, 7, M.

There are two primary considerations for the user's choice of the dynamic or static address sequence. First is the dynamic sequence makes each current measurement right after all the vectors in the pattern between the start and this measure point have just run. In that way, any nodes in the circuit under test that are subject to decay are still valid during the actual measurement. However, for large patterns, the dynamic sequence can be billions of cycles long requiring extensive test times.

The static sequence measures each current after executing only the vectors between measurement points. This makes large patterns run much faster. However, measurements at the end of large patterns, may be made seconds after the vectors in the first part of the pattern were run. Any dynamic nodes in the IC will have become invalid. However, circuits based on static logic will be measured correctly and quickly.

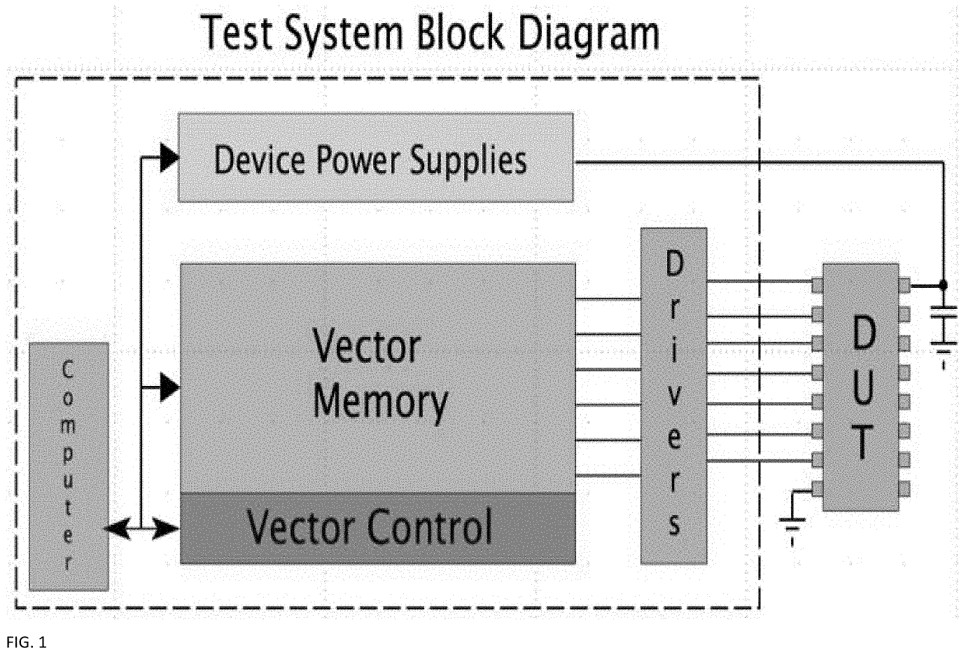

FIG. 1 shows an exemplary basic structure of the test hardware. A computer controls device power supplies. The computer can also load vectors into a vector memory and provides vector control. The vectors are provided to drivers that drive a device under test (DUT) such as a memory device, among others. A graphic display is connected to the computer to render graphs of the testing process. VectorEyes presents its data as a high-resolution graph. With the vertical axis showing the amount of current flowing into the DUT and the horizontal showing the vector address of the measurement.

The computer collects all the data at each measurement point, calculates the average and then writes the vector address and averaged value to the disk. The data is formatted such that any web language such as HTML5 can be used and a compatible device can view and manipulate the information once the test has completed.

The test system used to make these measurements includes the following features:
A digital subsystem that can present the vector stimulus information to the DUT
The vector addressing flexibility to execute the dynamic and static test sequences
Device power supplies that can provide the voltage and current required and the ability to report back to the computer the amount of current being consumed by the DUT
The speed of control and computation required to complete a set of measurements in a timely fashion. Being primarily an engineering tool, run times of minutes or even hours can be acceptable. But in a test system with slow computer command and control, sequences with thousands of vectors in the pattern could take many days to run.

The test system supporting VectorEyes has the capability to start a new vector pattern within 20 uS and make a supply current measurement every 37 uSec. A 1000 step vector pattern, running the dynamic sequence, stopping at every vector and making 1024 measurement can complete the task and plot the results in under 30 seconds. Tools that take hours and hours to run have limited use to an engineering team.

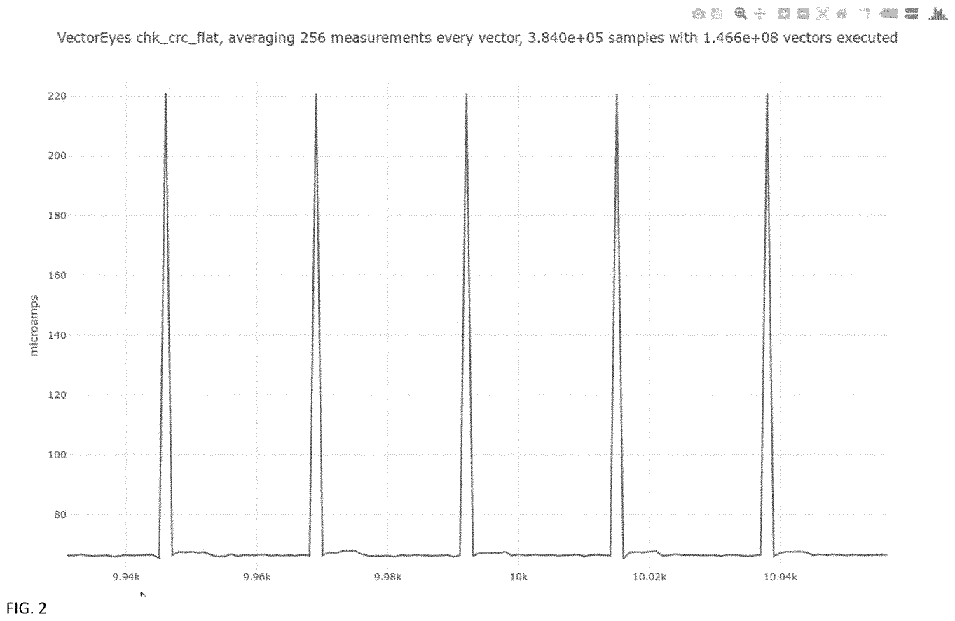

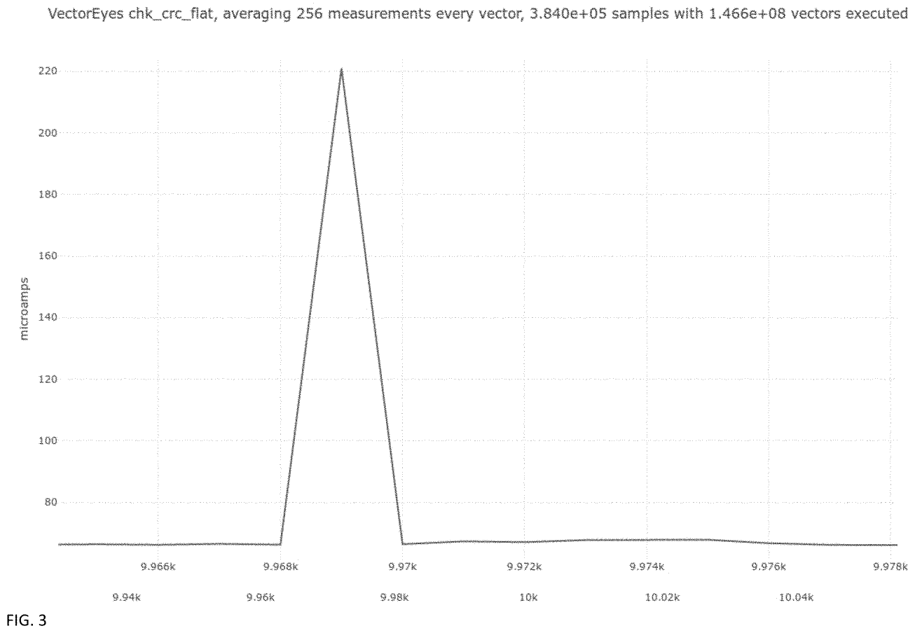

FIG. 2 below is an example of a Vector Eyes graph. The graphics tool allows the user to select regions of the plot for more detailed analysis. FIG. 3 below is an example of a zoomed-in view of the same data showing a one vector current spike. FIGS. 2, 3 and 4 are actual measurements of a commercially available FPGA. With the instant system, the test group has a way to correlate actual device performance with the parameters developed during the design simulations. Each change in the power should be explained by the design and simulation information. Miscorrelations invite further investigation via new diagnostic vector patterns and more VectorEyes measurements.

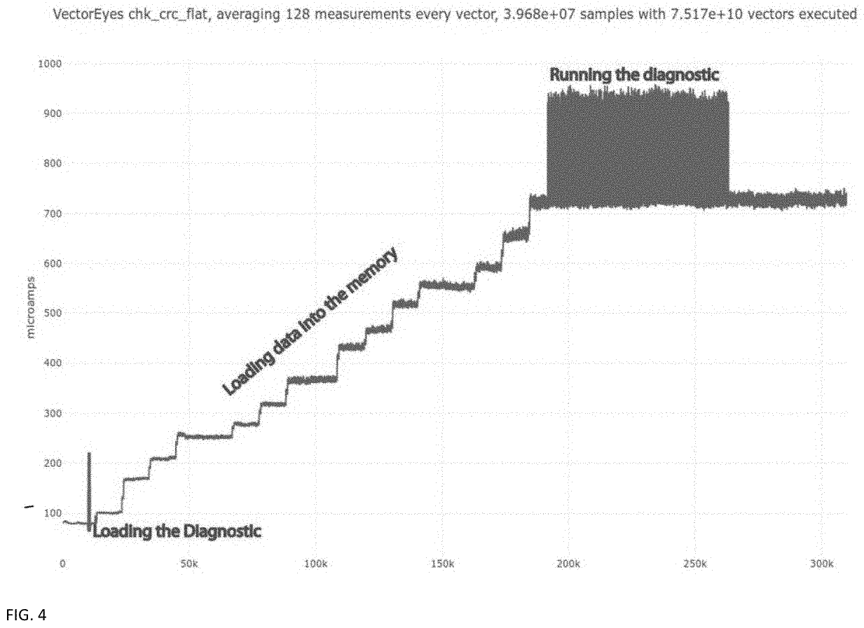

In FIG. 4, the VectorEyes plot makes functional state changes in the device under test identifiable. During this vector pattern, a Field Programmable Logic Array (FPGA) is programmed to self-test its own SRAM memory. The pattern first loads the self-test diagnostic pattern into the gates. Then the SRAM is loaded with data. And finally, the diagnostic is run to assure that all the bits of memory are operating correctly.

FIG. 4 identifies those regions on the VectorEyes plot. Any unexpected increase or decrease in current usage could signal: a fault coverage escapement of either a design error or a processing defect, a malfunction of the self-test diagnostic or a simulation error. Any of which would invite further investigation to assure proper device functionality. And many of these errors are extremely difficult to discover without VectorEyes.

Security

The VectorEyes capability can have positive impact on yet another aspect of the semiconductor industry. There is often fear that during design and fabrication, unauthorized circuits could be added to the design that would give certain individuals ways to usurp any security precautions. Semiconductor designers and manufacturers can use VectorEyes profiles to make sure that any unexpected operation of the chip is detected and analyzed. As one test expert stated, “You can't fool current.”

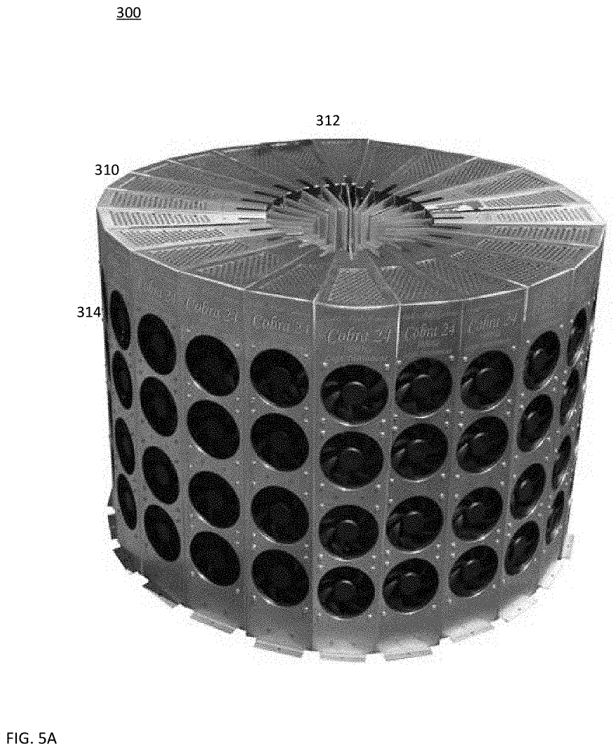

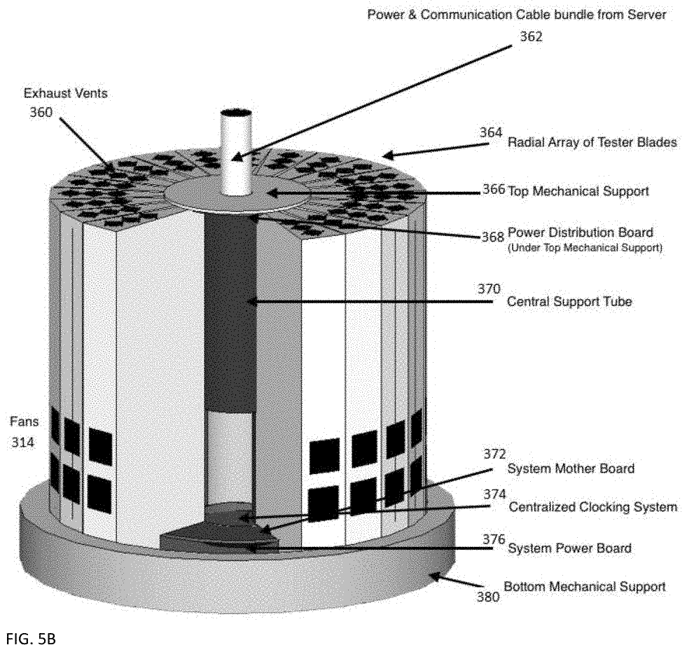

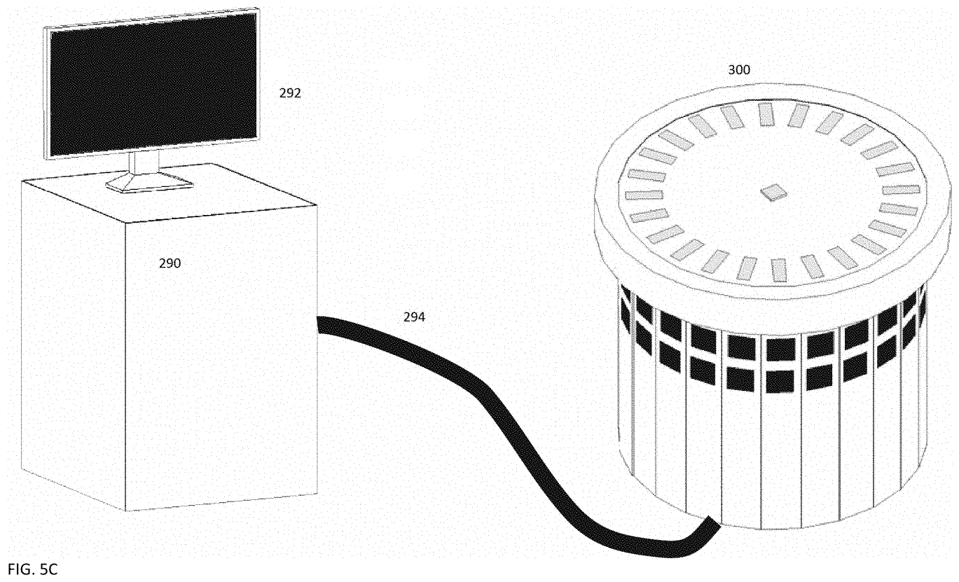

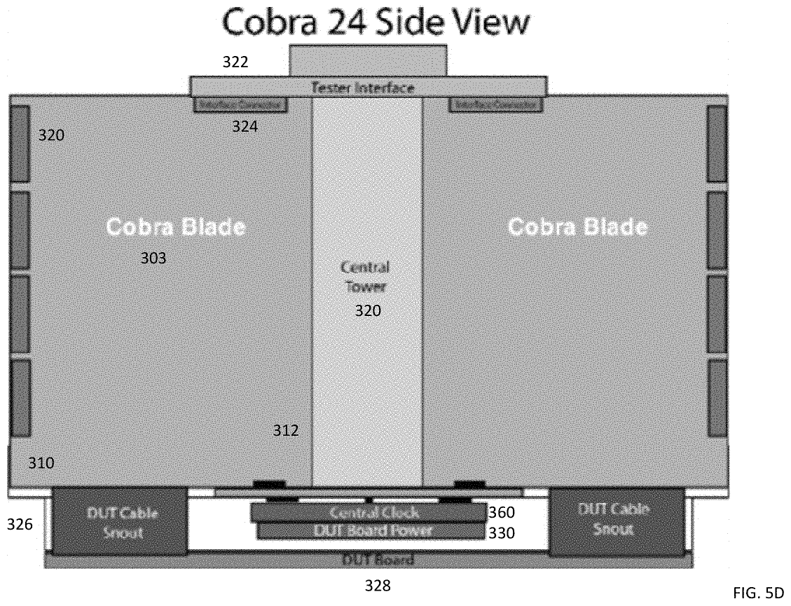

FIG. 5A shows an exemplary tester system called Cobra. The system has a cylindrical housing 300 that receives a plurality of tester boards with inner edge 312 and outer edge 310. The system also has a plurality of fans to cool the tester boards. One embodiment of Cobra is an advanced system for the automatic testing of semiconductor integrated circuits (IC). It is designed to be quick, quiet, and clean; providing customers with a repeatable, high-throughput, low-cost production test solution. Cobra utilizes the peak of technology to deliver dependable and efficient performance in a small, rugged package. The Cobra offers a “blade” approach to the problem of IC testing. Digital pins, precision DC sources, GHz amplifiers, time analyzers, among others, are all available as test instrument blades (TIB). Customers can select the set of TIBs to best satisfy their testing needs. This Application Specific approach allows one tester platform to provide focused solutions for such varied test problems as NAND FLASH memories and multi-gigabit serial communications chips.

FIG. 5B shows an exemplary tester with a four-blade cut away. Fans 314 are positioned on the outer edges of the system, in addition to exhaust vents 360 on top of the blades. The blades are concentrically arranged as a radial array 364 and rest on a bottom mechanical support 380. At the center of the blades is a power and communication cable bundle 362 and supported by a top mechanical support 366. A power distribution board 368 is positioned on a central support tube 370, and the board 368 is electrically connected to a system motherboard 372. A centralized clocking system 374 is also connected to the motherboard 372, as detailed below.

In one embodiment, the Cobra Test-head has 24 “slots” where tester's blades can be inserted into to add functionality to the Test-head. The Test-head supports a multitude of configurations with presently up to 1920 digital channels in a 900 mm×550 mm cylindrical package. The cylindrical nature of the system benefits the user by providing the shortest possible path between tester functions and the device under test (DUT). Each blade is contained in it own metal chassis with local cooling, mechanical support systems, and shields the electronics from EMF noise. Each Cobra test system will include a TIB chassis in all slots. Slots without active blades will hold “Dummy” blade chassis that maintain balance in the system. The system operates with any number of active blades from 1 to 24. The chassis protects the blade during shipping and handling, also makes a very user-friendly replaceable module. Each of the blades contained in the test head is electrically isolated from the other instruments or any other source. This “Floating” power system assures that each instrument is in the best possible “electrical noise environment” supporting high fidelity, high stability operation of all tester functions. Combined with the shielding provided by the instrument chassis, Cobra is one of the quietest test systems ever constructed. To support the high-density packaging embodied in the Test-head, the cooling system utilizes a computer controlled set of redundant, magnetically floating fans. Changes in room temperature or power duty cycles are managed by altering fan speeds and turning on heaters near critical instrument circuits—assuring stable temperatures and predictable instrument performance. The cooling controllers also monitor the 48 volt system supply to assure overall proper system performance. Should the temperature or the system supply be found faulty, the controller signals an “Alarm” and causes a system shut down. The controller also has a “Red or Green” indicator light which signals when the instruments are operating correctly or when there is a problem and the blade module needs replacement.

FIG. 5C shows the tester of FIG. 1 with a control computer 290 with a display 292. The computer 290 executes test software as described in more details below, and instructions as well as results are passed back and forth with the tester 300 through a cable bundle 294. In one embodiment, the cable bundle 294 is a PCI Express bus bundle that is shielded. PCI Express (Peripheral Component Interconnect Express), officially abbreviated as PCIe, is a high-speed serial computer expansion bus standard designed to replace the older PCI, PCI-X, and AGP bus standards. PCIe has numerous improvements over the older bus standards, including higher maximum system bus throughput, lower I/O pin count and smaller physical footprint, better performance-scaling for bus devices, a more detailed error detection and reporting mechanism (Advanced Error Reporting (AER)[1]), and native hot-plug functionality. More recent revisions of the PCIe standard support hardware I/O virtualization. PCIe is based on point-to-point topology, with separate serial links connecting every device to the root complex (host). Due to its shared bus topology, access to the older PCI bus is arbitrated (in the case of multiple masters), and limited to one master at a time, in a single direction. Furthermore, the older PCI clocking scheme limits the bus clock to the slowest peripheral on the bus (regardless of the devices involved in the bus transaction). In contrast, a PCIe bus link supports full-duplex communication between any two endpoints, with no inherent limitation on concurrent access across multiple endpoints. In terms of bus protocol, PCIe communication is encapsulated in packets. The work of packetizing and de-packetizing data and status-message traffic is handled by the transaction layer of the PCIe port (described later). Radical differences in electrical signaling and bus protocol require the use of a different mechanical form factor and expansion connectors (and thus, new motherboards and new adapter boards); PCI slots and PCIe slots are not interchangeable. At the software level, PCIe preserves backward compatibility with PCI; legacy PCI system software can detect and configure newer PCIe devices without explicit support for the PCIe standard, though PCIe's new features are inaccessible. The PCIe link between two devices can consist of anywhere from 1 to 32 lanes. In a multi-lane link, the packet data is striped across lanes, and peak data-throughput scales with the overall link width. The lane count is automatically negotiated during device initialization, and can be restricted by either endpoint. For example, a single-lane PCIe (x1) card can be inserted into a multi-lane slot (x4, x8, etc.), and the initialization cycle auto-negotiates the highest mutually supported lane count. The link can dynamically down-configure the link to use fewer lanes, thus providing some measure of failure tolerance in the presence of bad or unreliable lanes. The PCIe standard defines slots and connectors for multiple widths: x1, x4, x8, x16, x32. As a point of reference, a PCI-X (133 MHz 64-bit) device and PCIe device using four lanes (x4), Gen1 speed have roughly the same peak transfer rate in a single-direction: 1064 MB/sec. The PCIe bus has the potential to perform better than the PCI-X bus in cases where multiple devices are transferring data communicating simultaneously, or if communication with the PCIe peripheral is bidirectional. More details on the PCIe interface with the computer of FIG. 5C is detailed below.

FIG. 5D shows an exemplary side view of the system 300 where a central tower 320 is formed with the inner edges 312 of a plurality of concentrically positioned tester blades 303. The system has a plurality of test blades 303, each with plurality of connectors 320 that are positioned near the outer edge 310 that allows the blades 303 to intercommunicate. In addition, a tester interface 322 communicates with each blade through a top connector 324. The device under test (DUT) is positioned on a DUT board 328 that communicates with the tester blades 303 through a DUT cable snout 326. A DUT power system 330 and a central clock distribution system 360 are positioned under the central tower 320 and in electrical communication with the blades 303. The Cobra test head can be thought of as a nest for 1 to 24 test instrument blades.

One implementation of the Cobra instruments contains various standard features in addition to the circuits required to provide their specific functions, among others:
DC-to-DC conversion to create all the required voltages from the 48V bulk supply
Local control processor with memory
Synchronization Controller for Inter-Instrument Communication
DC Isolated PCi Express for communications with a controller
Standard “Nest” connector for connection to:
Isolated Buss
48V bulk supply
Master Clock
16-bit wide sync bus
Relay isolated connection to Mother for validation
Selected connector to test fixture (load board).

The Testhead provides the TIBs: mechanical support, power distribution, cooling, high-speed communications, advanced clocking and coherent synchronization. It is designed to provide a benevolent, supportive environment for optimized performance. A stable, low-noise electronic environment is necessary to fully assure the quality of microelectronic circuits during the test process, this is the core of The Cobra Test System. From its computer controlled cooling, to its ultra-low-noise power distribution process and isolated communications bus, Cobra is the rock-solid reference point demanded by integrated circuit engineering and manufacturing. FIGS. 4A and 4B detail the power distribution that provides the stable low noise power supply to the tester blades 303.

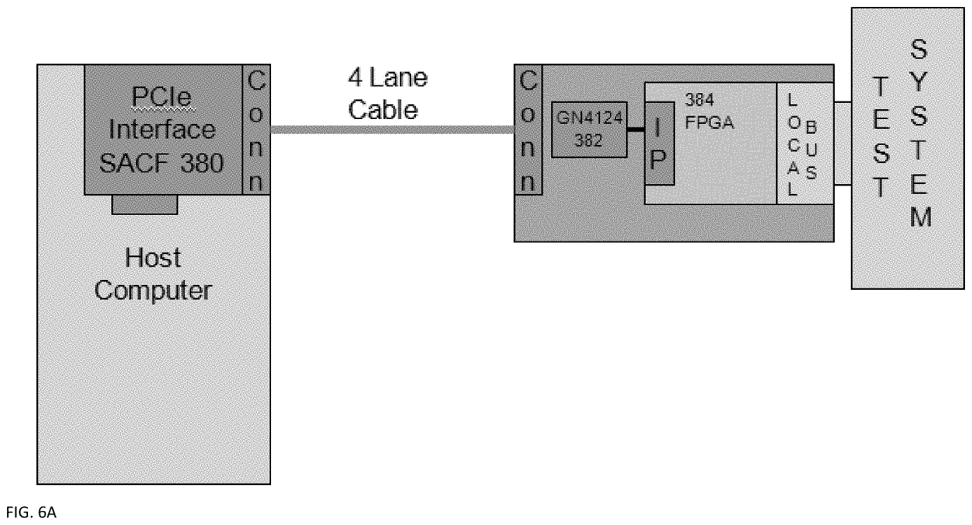

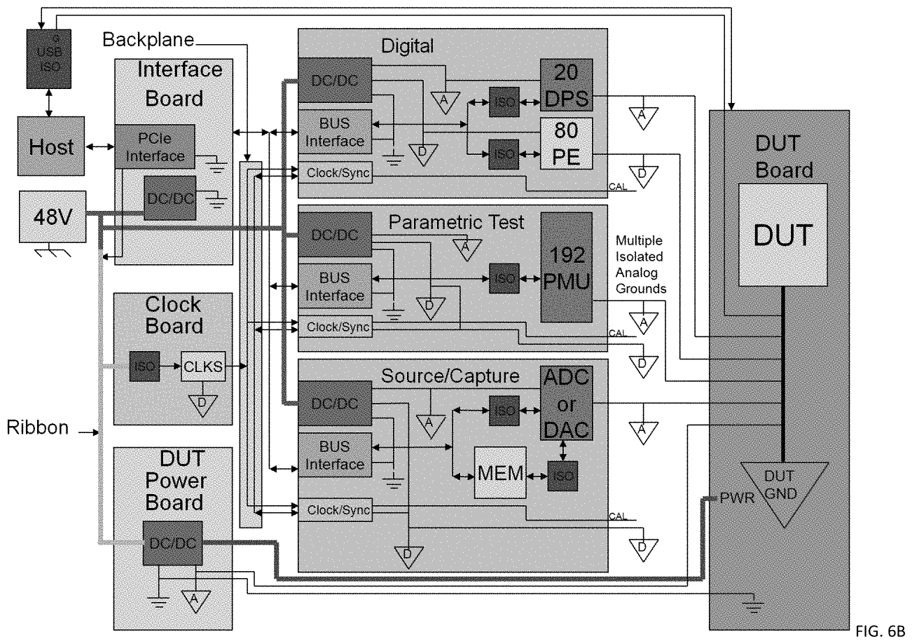

FIG. 6A shows an exemplary PCIe cable interface. FIG. 6 shows the relationship between the Host Computer 290 and the Test System 300. The system uses an adaptive semaphore signal to throttle the data transmission between the Host computer and the Test System. Since several serial interface protocols are used within each Blade, it is better not to run the communication at the slowest rate to accommodate the slowest device. This issue is avoided by using a “Self Addressing Circular Fifo” (SACF) 380 to receive data from the Host Computer. The SACF 380 is located on the Host Interface Board. Since the Host can send data faster than can be distributed through serial protocols, the system needs to throttle the data transfer. The SACF 380 stores several data transactions before the system can slow down the transfers. After the system can process the data and empty the Fifo, the system can request more data transfers. The time for these interactive transfers is dependent on the Blade requirements. For fast transactions data can be sent at 32 bits in about 200 nS in one implementation, but for long serial transactions the time becomes greater than 4 uS. Any required speed can be accommodated using this technique. Using this method the system can always transfer data at the maximum speed allowed by the hardware on each Blade.

FIG. 6B shows an exemplary arrangement for minimizing noise for multiple blade instruments. The system is designed from the start with the best possible noise isolation presented to the Device Under Test (DUT). The system contains 3 ground systems. The first is the Host Computer ground system, which should be avoided at the DUT. To accomplish this the system references the Host to Tester communication at the Host Computer ground potential. On each Blade isolation is provided for all the Digital and Analog circuits using 2 novel methods. The first method isolates the communication to the digital and digital input for the analog circuits. This isolated digital data is then referenced to an isolated digital ground. This ground potential is referred to as the digital isolated ground. In addition the system isolates the analog circuits from the digital isolated ground using an analog isolated ground reference. These isolated grounds are only tied together at the DUT. This prevents noisy ground currents from affecting the critical circuits on the Blade or at the DUT. The actual means of isolating these grounds is accomplished using DC to DC converters with a transformer to provide isolation between the primary and secondary. The power system architecture is a distributed 48 volts to all Blades with the isolation DC to DC converters providing the isolated lower voltages as required. The DC to DC converter transformers are implemented using windings provided by the multilayer PCB with a transformer core that clamps to the PCB. In one PCIe implementation, the following grounding scheme is used:

1. Most Instruments will have an Isolated Digital and an Isolated Analog. These will need to be tied together at the DUT.

2. The USB_GND will also need to be tied to the DUT ground if used.

3. The Slot #1 CAL ground signals on Ardent Block “A” pins A1 and A2 should only be required for Calibration and are not required to be tied to the DUT ground.

4. The User Sync associated Isolated Digital ground Ardent Block “B” pins B25 and B26 is only provided for a Scope sync. This signal is only available from selected Digital Instruments and should not be tied to the DUT ground. The User Sync signal and the grounds should go to a set of test points.

5. The GND_POWER on the 25th Connector pins 4, 5, and 6 is only used when controller device V48LB is required to generate special voltages on the DUT card. It should not be tied to the DUT ground.

Further embodiments of the present invention provide a method for testing a device under test. In a first step, an input signal is received from the device under test and information describing the input signal is written to a memory. In a second step, the information describing the input signal is read from the memory and an output signal is provided for the device under test based on the information describing the input signal read from the memory.

Further embodiments of the present invention provide an apparatus for configuring the ATE. The apparatus is adapted to configure the automatic test equipment to receive an input signal from a device under test and to write information describing the input signal to a memory. The apparatus is further adapted to configure the automatic test equipment to read the information describing the input signal from the memory 16 and to provide an output signal for the device under test based on the information describing the input signal read from the memory.

Further embodiments of the present invention provide a method for configuring the automatic test equipment. In a first step, the automatic test equipment is configured to receive an input signal from a device under test and to write information describing the input signal to a memory. In a second step, the automatic test equipment is configured to read the information describing the input signal from the memory and to provide an output signal for the device under test based on the information describing the input signal read from the memory. Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, some one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are preferably performed by any hardware apparatus.

The above described embodiments are merely illustrative for the principles of the present invention. It is understood that modifications and variations of the arrangements and the details described herein will be apparent to others skilled in the art. It is the intent, therefore, to be limited only by the scope of the impending patent claims and not by the specific details presented by way of description and explanation of the embodiments herein.

What is claimed is:

1. A method for testing a device under test (DUT), comprising:
receiving a test pattern for a functional test, wherein the test pattern includes a test vector, an expected test result, and an expected power consumption;
instructing the test system to run a repetitive loop using a selected functional test as the stimulus;
at selected steps in the functional test, measuring power consumption of the DUT; and
validating the DUT based on validating the test vector and the power consumption with one or more expected test result patterns and expected power consumption patterns.

2. The method of claim 1, wherein the DUT comprises an integrated circuit.

3. The method of claim 1, comprising specifying one or more sections of a functional test pattern for a measurement portion of a test and measuring power consumption.

4. The method of claim 1, wherein measuring power consumption comprises recording one or more currents being consumed by the DUT.

5. The method of claim 1, comprising processing data from one or more predetermined areas of interest without waiting for data from other areas of the vector pattern.

6. The method of claim 1, comprising selecting a test from one or more of: vector to start the functional test, vector to start making current measurement, vector steps between measurements, vector to stop testing, and a delay from stopping on a vector to making a subsequent measurement.

7. The method of claim 1, comprising selecting a number of power measurements to make at each vector being measured and averaging the measurements to reduce noise affecting power measurements.

8. effects of these bypass capacitors must be taken into consideration when interpreting DUT data.

9. The method of claim 1, comprising correlating actual device performance with the parameters developed during design simulations.

10. The method of claim 1, comprising correlating a change in power by the DUT with design and simulation information.

11. The method of claim 10, comprising capturing one or more new diagnostic vector patterns and measurements if a miscorrelation is observed.

12. The method of claim 10, wherein the change comprises an unexpected increase or decrease in power usage.

13. The method of claim 10, comprising determining from the change a fault coverage escapement of either a design error or a processing defect, a malfunction of the self-test diagnostic, or a simulation error.

14. The method of claim 1, comprising determining tampering or security breach in the DUT.

15. The method of claim 1, comprising determining and analyzing unexpected operation of the DUT.

16. The method of claim 1, comprising determining in the DUT one or more unauthorized circuits.

17. The method of claim 1, wherein power is consumed by one or more pins on the DUT, comprising tracking current of multiple supplies, at various voltages, as part of a DUT measurement.

18. The method of claim 1, wherein the power measured comprises a supply current.

19. A test system, comprising
a processor;
one or more driver coupled to the processor and to a device under test (DUT);
a data storage device to store
one or more test vectors; and
code for:
receiving a test pattern for a functional test, wherein the test pattern includes a test vector, an expected test result, and an expected power consumption;
instructing the test system to run a repetitive loop using a selected functional test as the stimulus;
at selected steps in the functional test, measuring power consumption of the DUT; and
validating the DUT based on validating the test vector and the power consumption with one or more expected test result patterns and expected power consumption patterns.

20. The system of claim 19, comprising code to detect security violation or tampering of the DUT.
